(19) United States
(12) Patent Application Publication
(10) Pub. No.: US 2009/0052029 A1
(43) Pub. Date: Feb. 26, 2009

(54) FUNCTIONAL FILMS FORMED BY HIGHLY ORIENTED DEPOSITION OF NANOWIRES

(75) Inventors: Haixia Dai, Mountain View, CA (US); Manfred Heidecker, Mountain View, CA (US); Benny Chun Hei Ng, Arcadia, CA (US); Hash Pakbaz, Hayward, CA (US); Michael Paukshto, Foster City, CA (US); Michael A. Spaid, Mountain View, CA (US); Cheng-I Wang, Foster City, CA (US)

Correspondence Address: SEED INTELLECTUAL PROPERTY LAW GROUP PLLC, 701 FIFTH AVE, SUITE 5400, SEATTLE, WA, 98104, US

(73) Assignee: CAMBRIOS TECHNOLOGIES CORPORATION, Mountain View, CA (US)

(21) Appl. No.: 11/871,721

(22) Filed: Oct. 12, 2007

Related U.S. Application Data
(60) Provisional application No. 60/862,957, filed on Oct. 25, 2006.
(60) Provisional application No. 60/829,292, filed on Oct. 12, 2006.

(51) Int. Cl. G02B 1/08; H01B 5/00; H05K 3/10; G02B 5/30

(52) U.S. Cl. 359/486; 174/128.1; 29/850; 977/762

(57) ABSTRACT

Optical films formed by deposition of highly oriented nanowires and methods of aligning suspended nanowires in a desired direction by flow-induced shear force are described.

### BACKGROUND

1. Technical Field

This invention is related to functional films comprising highly oriented nanowires and methods of aligning nanowires and forming highly ordered nanowire grids and networks.

2. Description of the Related Art

Optical films manage fundamental optical functions such as polarization, phase, reflection, refraction, wavelength and the like. They are therefore widely used in image displays, electronics and telecommunication devices. Specialty and high-end optical films have drawn particular interest because they can significantly improve image quality, enlarge view angles and enhance brightness of flat panel displays such as liquid crystal displays (LCD), plasma display panels (PDP) and organic EL viewing displays.

Optical films including polarizers and retarders (phase-shifting films) exhibit high degrees of optical anisotropy. These films are typically based on molecularly ordered material, which interacts with incident light differently depending on the angle of the incident light with respect to the orientation of the molecular components of the material.

Conventionally, optically anisotropic films can be formed by stretching or extending a polymer film. As a result, the molecular components of the polymer film, e.g., long chain polymer molecules, are aligned within the polymer film in the same direction (i.e., the direction of the extension). Such a polymer film can be used as, for example, a polarizer, which is capable of transforming unpolarized light (i.e., light wave vibrating in more than one plane) into polarized light (i.e., light wave vibrating in a single plane). In general, the light wave vibrating in a plane perpendicular to the direction of the molecular alignment is transmitted through the polarizer, whereas the light wave vibrating in a direction parallel to the direction of the molecular alignment is absorbed.

Another type of conventional polarizer is the wire-grid polarizer, which consists of a regular array of fine metallic wires on a transparent substrate (e.g., glass). An incident light (i.e., electromagnetic wave) can be linearly polarized in a direction perpendicular to the wires. More specifically, a wave component that vibrates perpendicularly to the wires is able to travel through the grid, whereas a wave component vibrating parallel to the wires is absorbed or reflected. For practical use, the separation distance (or “pitch”) between the wires must be less than the wavelength of the incident light, and the wire width should be a small fraction of this distance. This means that conventional wire-grid polarizers are generally used only for microwaves and for far- and mid-infrared light. To polarize visible light, metallic grids of much tighter pitches are necessary. Although advanced lithographic techniques can be used to create tight pitches, the technique is costly and does not allow for manufacturing wire-grids in large areas.

Accordingly, there remains a need for optical films that are associated with low manufacturing cost, high durability and large-area production.

### BRIEF SUMMARY

Nanowire-based functional films, such as optical films, are described. One embodiment describes a polarizer comprising: a substrate having a surface; and an array of nanowires arranged parallel to the surface, the nanowires further orienting along a principle axis, wherein, the principle axis is perpendicular to a polarization direction of the polarizer.

A further embodiment describes an optical film comprising: a matrix layer having a first refractive index, and an array of nanowires in the matrix layer, the nanowires having a second refractive index, wherein the nanowires are arranged parallel to a surface of the matrix layer and orient along a principle axis.

A further embodiment describes a conductive film comprising: a first population of nanowires aligned in a first direction; and a second population of nanowires aligned in a second direction, the first direction and the second direction being transverse from one another, wherein the first population of nanowires and the second population of nanowires form a conductive network.

A further embodiment describes a method of aligning nanowires comprising: depositing a first population of nanowires in a first fluid on a substrate, the nanowires in the first population having respective longitudinal orientations; applying a first shear force in a first direction to allow substantially all the first population of nanowires to align their longitudinal orientations with the first direction; immobilizing the first population of nanowires on the substrate; depositing a second population of nanowires in a second fluid on the substrate, the nanowires in the second population having respective longitudinal orientations; applying a second shear force to in a second direction to allow substantially all the second population of nanowires to align their longitudinal orientations with the second direction, wherein the first direction and the second direction are transverse to one another; and immobilizing the second population of nanowires on the substrate, the first population of nanowires and the second population of nanowires forming a network.

A further embodiment describes a method of forming a transparent conductor comprising: forming a conductive network on an optically clear substrate, the conductive network including a first population of nanowires and a second population of nanowires, the first population of nanowires being oriented longitudinally along a first direction under a first shear force; the second population of nanowires being oriented longitudinally along a second direction under a second shear force; and depositing a matrix on the conductive network, wherein the first direction and the second direction are transverse to one another.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and have been selected solely for ease of recognition in the drawings.

FIGS. 1A-1B illustrate a shear flow causing suspended anisotropic particles to reorganize in a fluid.

FIG. 2A shows an absorptive polarizer based on highly ordered nanowires.

FIG. 2B shows a top view of a reflective polarizer based on highly ordered nanowires.

FIG. 3 shows light recycling by using a reflective polarizer according to one embodiment.

FIG. 4 shows a cross-sectional view of a wire-grid polarizer.

FIGS. 5A-5C show the correlation between nanowire density and degree of polarization.

FIGS. 6A-6B show a quarter wave plate based on highly ordered nanowires according to one embodiment.

FIG. 7 shows retardation as a function of position of an aligned nanowire film on a glass substrate.

FIG. 8A shows an anisotropically conductive film.

FIG. 8B shows a nanowire network.

FIGS. 9A-9C show nanowire alignment caused by flow-induced shear forces.

FIGS. 10A and 10B show alignment of nanowires when suspended in liquid crystal.

FIG. 11 shows the images of aligned nanowire film created by multiple coating passes.

FIGS. 12 and 13 show the optical properties of the aligned nanowire films of FIG. 5.

FIGS. 14A-14B show schematically sequential depositions and alignments of nanowire.

FIG. 15 shows an example of a transparent conductor.

FIG. 16 shows another example of a transparent conductor including a matrix.

FIG. 17 shows a substrate coated with an adhesion layer according to a pattern.

FIGS. 18A-18B are images of non-random networks formed of silver nanowires oriented in two main directions.

### DETAILED DESCRIPTION

Functional films based on ordered arrays of nanowires are described. Generally speaking, the nanowires are deposited in a fluid phase and aligned under a flow-induced or mechanical shear force. Depending on design parameters such as geometry, loading density and spatial arrangement of the nanowires, the functional films exhibit useful optical properties such as optical anisotropy (e.g., optical birefringence). Optical anisotropy refers to non-uniform spatial distribution of optical properties, including light transmission, polarization, phase changing, refraction, reflection and the like. Thus, the functional films can be optical films that manage optical behaviors.

In addition, the functional films can be electrically conductive when the nanowires form a conductive network. In particular, the functional films include transparent conductors that are electrically conductive and optically transparent.

“Nanowires” refer to anisotropic nanostructures or particles in which at least one cross sectional dimension (diameter) is less than 500 nm, and preferably less than 100 nm, and more preferably less than 50 nm. Typically, the nanowire has an aspect ratio (length:diameter) of greater than 10, preferably greater than 50, and more preferably greater than 100. Typically, the nanowires are more than 500 nm, or more than 1 μm, or more than 10 μm in length.

In certain embodiments, it is necessary to control the nanowire geometry. For example, the nanowires in wire grid polarizers are typically straight. Synthetic parameters can be adjusted to produce nanowires of certain length, aspect ratio and straightness.

The nanowires can be formed of any material, including conductive, dielectric, and insulating material. For example, nanowires that are electrically conductive can be formed of metal, metal oxide, polymer fibers or carbon nanotubes.

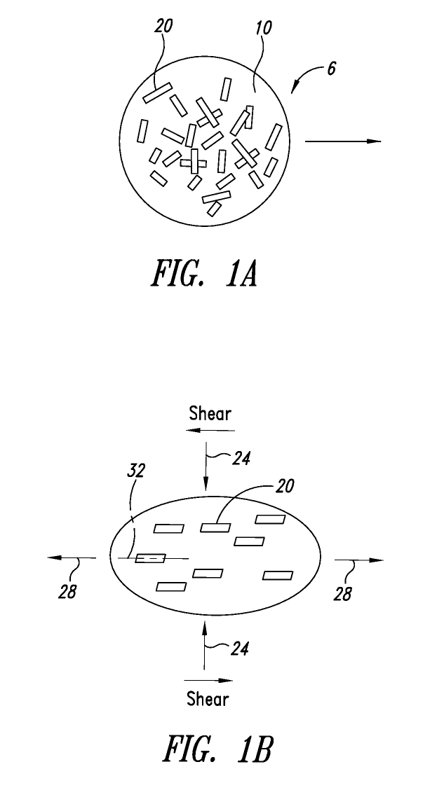

As will be discussed in more detail below, alignment of the nanowires can be achieved by, for example, applying a shear force to a fluid suspension of the nanowires. FIG. 1A illustrates a spherical section 6 of a fluid dispersion 10. Anisotropic particles 20 are suspended in random orientations in the fluid dispersion 10. In a flowing state, different parts of the fluid dispersion effect different velocities, such that a velocity gradient is generated. The velocity gradient manifests as a shear force, which causes a reorganization of the anisotropic particles 20 (FIG. 1B). More particularly, the shear force has the effect of applying compression 24 and tension 28 to the spherical section 6 shown in FIG. 1A. The result is a net alignment of the anisotropic particles 20 along their respective longitudinal axis 32.

1. Optical Films

The optical films described herein are suitable as polarizers (including absorptive and reflective polarizers) and retarders (including half wave or quarter wave retarders). The optical films can be used independently, be incorporated in a matrix and laminate on a substrate, or in combination with other optical films in a multilayer structure.

Thus, one embodiment describes a polarizer that converts an unpolarized incident electromagnetic wave into a linearly polarized wave. Such a polarizer comprises: a substrate having a surface, an array of nanowires arranged parallel to the surface, the nanowires further orienting along a principle axis, wherein the principle axis is perpendicular to a polarization direction of the polarizer.

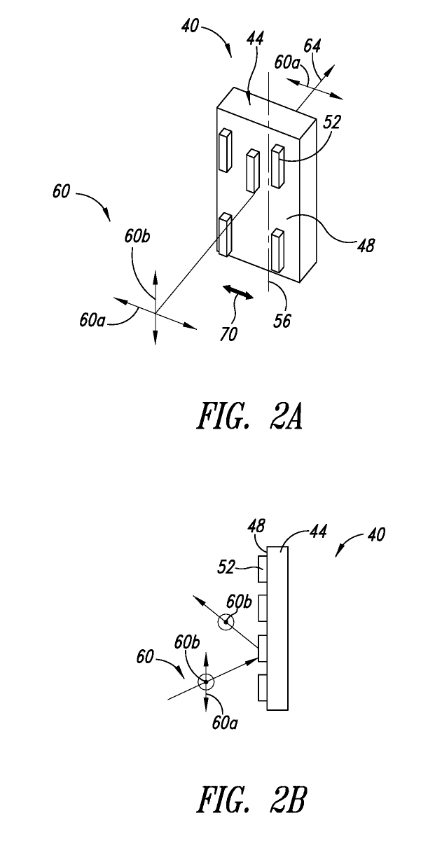

FIG. 2A illustrates schematically a polarizer 40 (e.g., a wire-grid polarizer) comprising a substrate 44 having a surface 48. An array of nanowires 52 are arranged parallel to the surface 48. The nanowires 52 further orient along a principle axis 56.

As shown, an incident unpolarized electromagnetic wave (e.g., light) 60 is represented by two orthogonal polarization states, i.e., a horizontally vibrating component 60a and a vertically vibrating component 60b. The components 60a and 60b are both perpendicular to the direction of the light propagation 64. The wave 60 enters the polarizer 40 and only the horizontally vibrating component 60a transmits through. In other words, the polarizer 40 has a polarization direction 70, which is perpendicular to the principle axis 56, i.e., the direction of the nanowire alignment.

In this illustration, the horizontally vibrating component 60a can also be referred to as a p-polarized component, known customarily as a polarized component polarized in the plane of the incident light 60. Similarly, the vertically vibrating component 60b can also be referred to as s-polarized component, indicating it is polarized perpendicular to the plane of the incident light 60. As shown in FIG. 2A, the s-polarized component 60b is not transmitted through the polarizer 40. Instead, it is absorbed or lost due to Joule heating of the wires.

FIG. 2B illustrates that the polarizer can be reflective. A top view of the polarizer 40 is shown. As in FIG. 2A, the incident light 60 comprises the p-polarized component 60a and the s-polarized component 60b. While the p-polarized component is transmitted through the polarizer (as shown in FIG. 2A), the s-polarized component reflects off the nanowire. This property makes reflective polarizers a desirable optical element for enhancing light efficiency by “light recycling’ in all types of lighting screens, including LCD, PDP, hand-held devices, cell phones and the like.

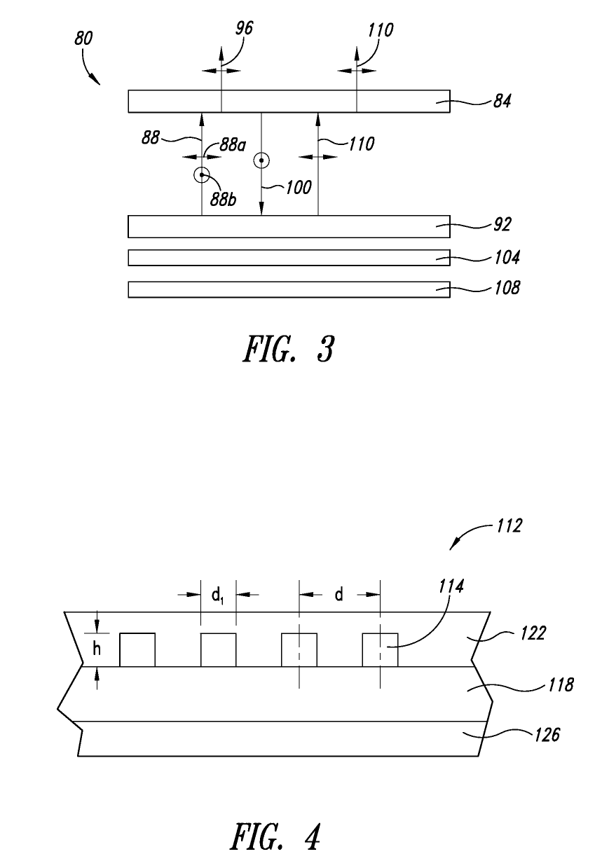

FIG. 3 illustrates an imaging device 80 that recycles at least a portion of the light reflected from a reflective polarizer 84 through polarization transformation. More specifically, unpolarized light 88 (from a light source 92) is incident on the reflective polarizer 84. As discussed above, the unpolarized light 88 comprises two polarization states orthogonal to one another: the p-polarization 88a and the s-polarization 88b. The reflective polarizer 84 allows the p-polarized light 96 to transmit, and reflects the s-polarized light 100 back in the direction of the incident light. It should be understood that, for a reflective polarizer that produces two output light beams (transmission and reflection), typically only one of them is fully polarized. The other one contains a mixture of polarization states. For purpose of simplicity, both the transmitted light 96 and the reflected light 100 are illustrated as fully polarized.

The reflected light 100 undergoes polarization transformation through the use of additional optical films including a quarter wave retarder 104 and a reflective layer 108. Light 110 is reflected back from the reflective layer 88. Due to the quarter wave retarder, its polarization direction is rotated by 90 degrees from its original source (i.e., reflected light 100). Light 110 is capable of transmitting through the reflective polarizer 84. Therefore, at a given power consumption, reflective polarizers (in combination with other optical films) can recycle light that otherwise would have been absorbed by the polarizer. As a result, the output light intensity (or brightness) can be enhanced without increasing the intensity of the light source.

As shown in FIGS. 2A-2B, the spatial arrangement of the nanowires, for example, the direction of their orientation is directly related to the polarization direction of the polarizer. In addition, the geometry, size and the spacing in between (pitch) the nanowires are also parameters that determine the polarization performance.

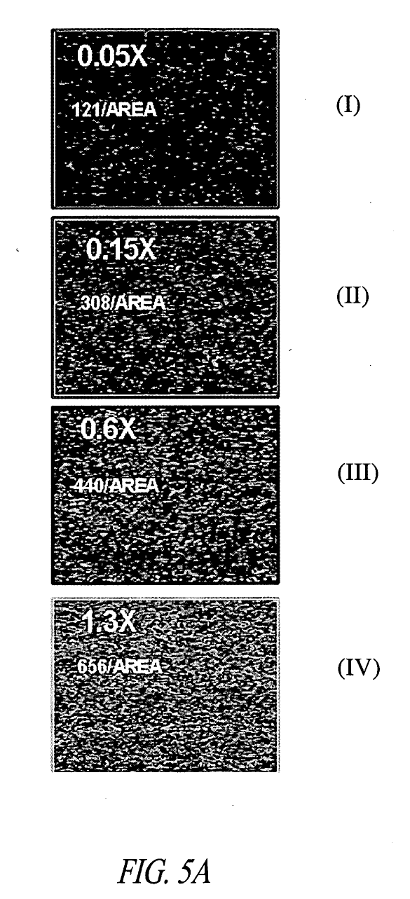

FIG. 4 illustrates some of the design parameters in a cross-sectional view of a wire-grid polarizer 112. An array of parallel conductive nanowires 114 is arranged on a substrate 118 (e.g., glass). In this illustration, a matrix layer 122 (e.g., a top coat) is positioned on the substrate 88, the matrix layer being a transparent material incorporating the nanowires. An optional anti-reflective layer 126 is positioned on the opposite side of the substrate 118 from the nanowires 114.

The nanowires are as defined herein. Preferably, the nanowires are metallic wires of, for example, silver or aluminum. The diameters (d₁) of the nanowires are in the range of about 100 nm to 150 nm. The heights (h) of the nanowires are in the range of about 100 nm to 200 nm. To ensure the alignment of the wire grid, the nanowires should be substantially straight, i.e., the nanowire should allow for no more than 10 degrees of deviation from its general longitudinal direction, and preferably, no more than 5 degrees of deviation. Although uniformity in the size and spacing of the nanowires is preferred, it is not necessary to form the structure illustrated above.

A fill factor (d/d1), d being the spacing between two adjacent nanowires, is also a parameter that affects the polarization performance, including the transmittance vs. reflection in a reflective polarizer. Typically, the fill factor is in the range of about 0.1 to 0.6, or in the range of about 0.15-0.25, or in the range of about 0.4-0.6. It has been found that low fill factor (less than 0.26) is associated with higher efficiency of light recycling, see, e.g., U.S. Published Application No. 2006/0061862.

The polarizers described herein comprise parallel nanowires that have much reduced diameters (d₁) and spacings (d) as compared to the metal wires in the conventional wire-grid polarizers. The polarizers thus created have high isolation and low insertion loss. In addition, these polarizers are capable of polarizing light in the visible range (between about 400 nm-700 nm).

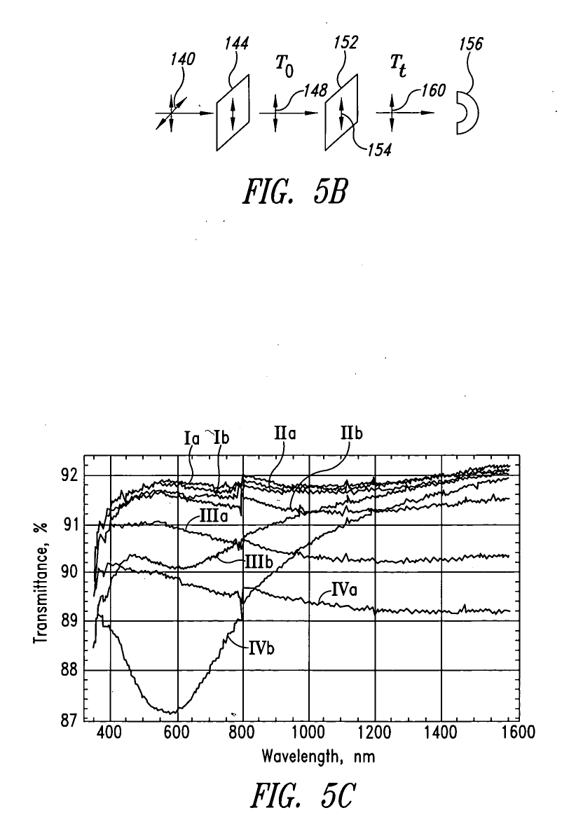

Moreover, the density of the nanowires on the surface of the substrate also correlates to polarization. Wire density refers to number of nanowires per unit area (e.g. μm²). The wire density is determined, in part, by the concentration of nanowire dispersion deposited on the surface of the substrate. FIGS. 5A-5C illustrate the density-dependence of the degree of polarization using a nanowire-based polarizer. FIG. 5A shows the dark field microscopic images of four nanowire-based polarizer samples (I)-(IV) in the order of increasing wire density (from 121/area to 656/area) prepared from 0.05-1.3 on a relative concentration scale.

FIG. 5B shows that unpolarized light 140 is linearly polarized by a first polarizer 144. The linearly polarized light 148 is incident on a nanowire-based polarizer 152 having a polarization direction 154. As discussed above, the polarization direction is perpendicular to the orientation of the aligned nanowires (see, FIG. 1A). A detector 156 measures the transmittance (T %) of the polarized light 160 exiting the nanowire-based polarizer 148.

FIG. 5C shows the transmittance data measured for samples (I)-(IV). For each sample, T % is measured by orienting the polarizer 148 such that the polarization direction 154 is parallel to the polarized light 148 (shown in FIG. 5A), as well as by orienting the polarizer 148 such that the polarization direction is perpendicular to the polarized light 148 (not shown). Thus, the transmission data for sample (I) are shown as Iₐ (parallel) and I_{b} (perpendicular), for sample (II) are shown as IIₐ (parallel) and II_{b} (perpendicular), and so forth. As shown, the degree of polarization, as indicated by the difference of transmissions between parallel polarized light and the perpendicularly polarized light, increases with increasing wire density on the polarizer.

Another embodiment describes a birefringent optical film having two different refractive indices. More specifically, the optical film comprises: a matrix layer having a first refractive index and an array of nanowires in the matrix layer, the nanowires having a second refractive index, wherein the nanowires are arranged parallel to a surface of the matrix layer and oriented along a principle axis.

These optical films are suitable as retarders, which manipulate polarized light through phase-shifting. In general, light entering a birefringent material is refracted into two orthogonally polarized beams. These two beams travel through the birefringent material in different velocities. Typically, the beam polarized along the direction with the smaller refractive index (fast axis) travels more rapidly, whereas the beam polarized along the direction with the larger refractive index (slow axis) travels more slowly. As a result, the polarized beams exiting the retarder are phase shifted. If one polarized beam is phase shifted in relation to the other (orthogonally polarized) beam by λ/4 (or 90 degree in phase), the retarder is a quarter wave plate. As is known, a quarter wave plate converts linearly polarized light into circularly polarized light or vice versa. Phase shifts at other degrees are also possible by adjusting the angle between the fast axis of the retarder and the incident polarization direction.

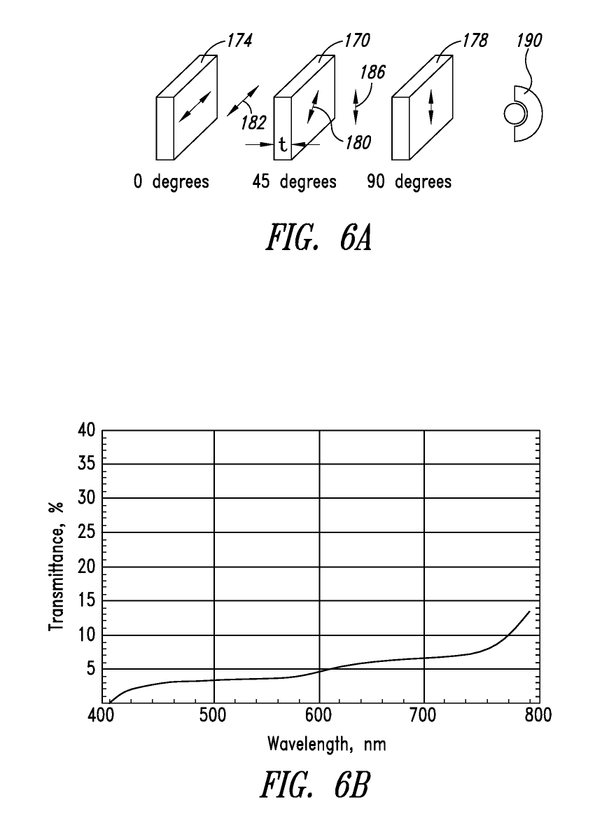

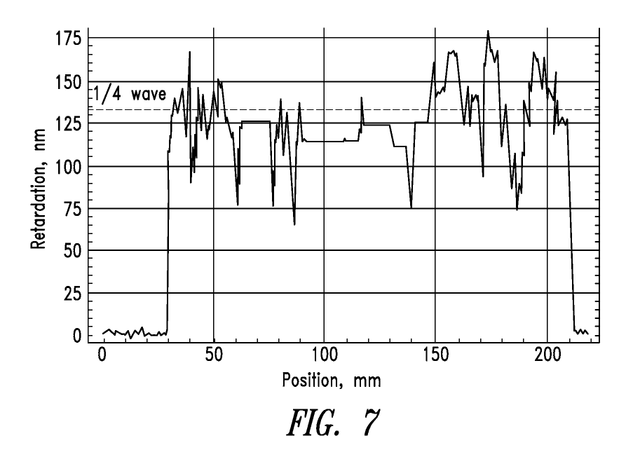

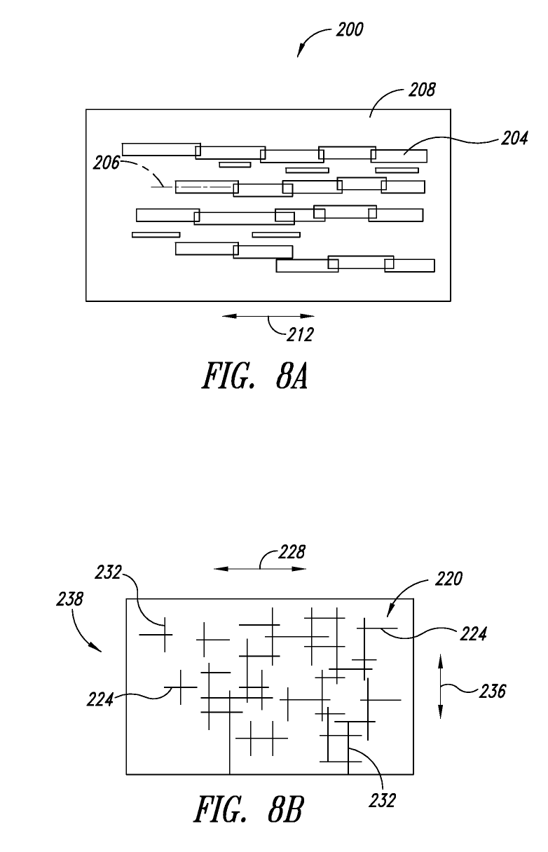

FIG. 6A illustrates a nanowire-based quarter wave plate positioned between two cross polarizers to test the conversion of linearly polarized light into a circularly polarized light. More specifically, the nanowire-based quarter wave plate 170 is placed between a first linear polarizer 174 and a second linear polarizer 178, the two polarizers having orthogonal polarization directions. The quarter wave plate 170 is placed so its fast axis 180 is at 45 degree angle with respect to the direction of polarized light 182. The light 186 exiting the quarter wave plate 170 is polarized 90 degrees from the polarization of its original source (i.e., polarized light 182). The polarized light 186 can transmit through the second linear polarizer 178 and be detected by a detector 190.

As is known, in the absence of the quarter wave plate 174, the cross polarizers 174 and 178 will black out an unpolarized incident light beam. The presence of the quarter wave plate causes a phase shift of the polarized light 182 and rotates its polarization by 90 degrees. This allows for detection of the transmitted polarized light through the second polarizer 178. FIG. 6B shows the detected transmission in the wavelength range of between 400 nm to 800 nm.

Optical retardation R is a function of the difference of the two refractive indices and the thickness (t) of the retarder plate. Thus, the amount of retardation can be tuned for different applications. For example, optical films that have a relatively small amount of retardation (˜13 nm) can be used in LCOS applications (liquid crystal on silicon). Optical films formed of a thicker layer of aligned nanowires have higher retardations. They can serve as quarter wave plates. FIG. 7 shows retardation data as a function of position of an aligned nanowire film on a glass substrate. An average retardation of the film reaches approximately 130 nm, which is a value typically required for a quarter wave plate.

2. Conductive Films

In other embodiments, the functional film comprises aligned conductive nanowires and exhibits anisotropic electrical conductivity in the direction of the alignment.

FIG. 8A shows an anisotropically conductive film 200. Conductive nanowires 204 are deposited on a substrate 208 and are oriented in a single direction 212. Due to the high aspect ratio of the conductive nanowires, connectivity of the nanowires along direction 212, which is aligned with the longitudinal axes 216 of the nanowires, can be preferentially established.

In other embodiments, the functional films comprise an efficiently interconnected network of conductive nanowires and are optically transparent as well as electrically conductive. These functional films are suitable as transparent electrodes for power supplies in flat liquid crystal displays, touch panels, and electroluminescent devices. They are also used as anti-static layers and electromagnetic wave shielding layers. Unlike metal oxide-based conductive films, nanowire-based conductive films are flexible and durable. Moreover, the deposition of nanowires can be achieved in an atmospheric environment by high throughput processes. See, e.g., U.S. Provisional Application Nos. 60/707,675, filed Aug. 12, 2005; 60/796,027, filed Apr. 28, 2006; and 60/798,878, filed May 8, 2006, in the name of Cambrios Technologies Corporation, the assignee of the present application, which applications are incorporated herein in their entireties.

When nanowires are deposited on a substrate, they typically assume random orientations. As a result, a significant portion of the nanowires may not form part of a conductive network, thus contributing only to light absorption without enhancing conductivity. Increasing the density of these randomly oriented nanowires may potentially lead to better conductivity, but possibly at the cost of reducing optical clarity (higher optical density). However, nanowires oriented in well-defined directions can form interconnecting networks. These networks increase the efficiency of connectivity between individual wires and reduce the number of wires that are only contributing to optical density.

FIG. 8B shows a network of interconnected conductive nanowires comprising a first population of nanowires 224 aligned in a first direction 228, and a second population of nanowires 232 aligned in a second direction 236, the first direction 228 and the second direction 236 transverse from one another. “Transverse” refers to one axis or direction being positioned at an angle from another axis or direction. In various embodiments, the first direction 228 and the second direction 236 cross at an angle of at least 30°, or at least 60°, or more typically, at 90°.

3. Fabrication of the Functional Films

Highly ordered nanowire-based films have been demonstrated to show useful optical and/or electrical properties. As will be discussed in more detail below, nanowires are caused to orient along a principle axis (aligned with their respective longitudinal axes). In general, nanowires can be aligned by, for example, Langmuir-Blodgett film alignment; flow-induced alignment, application of mechanical shear force, and mechanically stretching a thin film of randomly-oriented nanowires in a polymer matrix.

### Nanowires

In one embodiment, the nanowires are metal nanowires formed of plain metal or metal alloy. Examples of the metal nanowires include, without limitation, silver, gold, copper, nickel, and gold-plated silver. Metal nanowires can be synthesized according to the methods described in, e.g., Y. Sun, B. Gates, B. Mayers, & Y. Xia, “Crystalline silver nanowires by soft solution processing”, Nanoletters, (2002), 2(2) 165-168.

In other embodiments, the nanowires are mineralized or plated biological substances. More specifically, certain biological substances can function as templates or scaffolds, on which pre-formed nanoparticles can bind directly. Alternatively, nanoparticles can be nucleated out of a solution phase in the presence of the biological substances. For purpose of this application, the biological substances typically have elongated shapes and are rich in peptides, which have been shown to have affinities for metallic or semiconductive nanoparticles. The nanoparticles bound to the biological substance can fuse into a nanowire, which has a similar aspect ratio as the underlying template. The above process is also referred to as “mineralization” or “plating”.

For example, biological substances such as viruses and phages (e.g., M13 coliphage) have been demonstrated to mineralize to form metallic or semiconductive nanowires. In certain embodiments, these biological substances can be engineered to exhibit selective affinity for a particular type of metal. Examples of metals that can be plated on biological substances include, without limitation, silver, gold, copper and the like. More detailed description of nanowire biofabrication can be found in, e.g., Mao, C. B. et al., “Virus-Based Toolkit for the Directed Synthesis of Magnetic and Semiconducting Nanowires,” (2004) Science, 303, 213-217. Mao, C. B. et al., “Viral Assembly of Oriented Quantum Dot Nanowires,” (2003) PNAS, vol. 100, no. 12, 6946-6951; Mao, C. B. et al., “Viral Assembly of Oriented Quantum Dot Nanowires,” (2003) PNAS, 100(12), 6946-6951, and U.S. Provisional application Ser. Nos. 10/976,179 and 60/707,675.

Other exemplary biological substances that can be used as templates include peptide fibers and filamentous proteins. These templates can self-assemble into long strands of tens of microns in length. Advantageously, they can be synthesized to have even larger aspect ratios than phages. Large-scale manufacture of proteins, such as enzymes used in detergent additives, is well developed. More significantly, association sites can be incorporated into the protein structure in a controlled manner. These association sites encourage and facilitate the assembly of the protein strands to form an interconnected network.

In another embodiment, the nanowires are seeded biological substances. As described above, certain biological substance can bind to or nucleate nanoparticles. In this embodiment, the biological substance can be initially bound to a seed material layer either through direct binding or nucleation. The seeding material layer comprises nanoparticles that catalyze the growth of a conductive material. For example, when a seed material is exposed to a precursor of a conductive material in a solution phase (e.g., metal ions), the seed material catalyzes the conversion of the precursor into the conductive material (e.g., a metal layer). The conductive material forms a continuous layer over the seed material layer. This process is also within the definition of “plating”.

According to this embodiment, the seeded biological substances can be deposited and oriented, followed by a plating process. The seeded biological substances are therefore nanowires that may not necessarily be conductive per se, but which become conductive after the plating process. Suitable biological substances include, but are not limited to, elongated-shaped viruses, phages and peptide fibers and DNA. Suitable seeding material includes, without limitation, nanoparticles of Ag, Au, Ni, Cu, Pd, Co, Pt, Ru, Ag, Cr, Mo, W, Co alloys or Ni alloys. The conductive material that can be subsequently plated includes metals, metal alloys and conductive metal oxides, for instance, Cu, Au, Ag, Ni, Pd, Co, Pt, Ru, Ag, Cr, W, Mo, Co alloys (e.g., CoPt, CoWP), Ni alloys (e.g., NiP, NiWP), Fe alloys (e.g., FePt), indium oxide, indium tin oxide and the like. More details regarding the use of seeds or seed layers to direct functional layer formations are described in co-pending U.S. provisional application No. 60/680,491, entitled “Biologically Directed Seed Layers and Thin Films”, filed May 13, 2005, in the name of Cambrios Technologies, which reference is incorporated herein in its entirety.

### Substrate

“Substrate” refers to any material onto which nanowires are deposited. The substrate can be rigid or flexible. Preferably, the substrate is also optically clear, i.e., light transmission of the material is at least 80% in the visible region (400 nm-700 nm).

Suitable rigid substrates include, for example, glass, polycarbonates, acrylics, and the like. In particular, specialty glass such as alkali-free glass (e.g., borosilicate), low alkali glass, and zero-expansion glass-ceramic can be used. The specialty glass is particularly suited for thin panel display systems, including Liquid Crystal Display (LCD).

Suitable flexible substrates include, but are not limited to: polyesters (e.g., polyethylene terephthalate (PET), polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, and the like), cellulose ester bases (e.g., cellulose triacetate, cellulose acetate), polysulphones such as polyethersulphone, polyimides, silicones and other conventional polymeric films. Additional examples of suitable substrates can be found in, e.g., U.S. Pat. No. 6,975,067, and U.S. Provisional Application No. 60/798,878.

### Alignment by Shear Force

As noted herein, a shear force can cause an alignment of nanowires suspended in a fluid. In certain embodiments, the shear force is developed when parts of a fluid move relative to one another and create a velocity gradient. As used herein, a “fluid” includes any medium in which the nanowires can form a uniform dispersion. Suitable fluid includes any liquid and gas. For example, aqueous or organic solvents, liquid crystals, can be used.

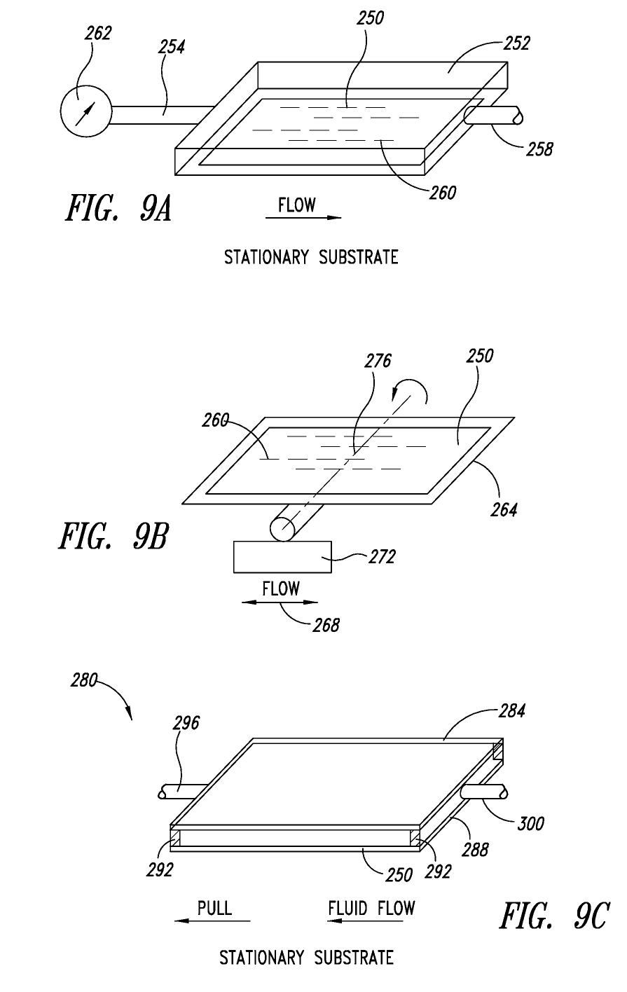

Any type of flow field in which a flow-induced shear force can be developed is suitable for aligning the nanowires. In one embodiment, as illustrated in FIG. 9A, a substrate 250 is placed in a platform 252. The platform 252 includes an inlet 254, an outlet 258 and a pump 260. A fluid dispersion of nanowires (not shown) can be directed and flowed onto the substrate 250 from the inlet 254. The substrate 250 remains stationary during the flow. As the fluid dispersion flows across the substrate to the outlet 258, substantially all the nanowires 260 orient their longitudinal dimensions along the flow direction (represented by a single-head arrow.)

As used herein, “substantially all” refers to at least 80% of the nanowires being oriented within 10° of a desired direction. More typically, at least 90% of the nanowires are oriented within 10° of a desired direction. Accordingly, the thus oriented nanowires are substantially parallel to each other.

In another embodiment, the substrate 250 can be placed on a pivoting platform 264, as illustrated in FIG. 9B. The pivoting platform 264 is supported by a pivot 268 driven by a motor 272. A fluid dispersion of nanowires 260 is deposited on the substrate 250 in a container (not shown). The pivoting platform 264 shakes or rocks the substrate 250 by tilting a certain angle from the pivoting axis 276. In this embodiment, the fluid flow caused by the rocking motion oscillates along an axis orthogonal to the pivoting axis (e.g., the flow direction is represented by a double-headed arrow). The nanowires 260 are aligned along the direction of the flows.

In a further embodiment, a substrate can be pulled through a fluid dispersion, causing a shear force that aligns the nanowires suspended in the fluid dispersion. FIG. 9C shows a Hele-Shaw cell 280 in which a top flat plate 284 is placed on a bottom flat plate 288 and spaced therefrom by spacers 292. The substrate 250 is placed on the bottom flat plate 288. A fluid dispersion of nanowires 260 is deposited in between the top plate 284 and the substrate 250. The fluid dispersion is in contact with the top plate 284 and can be stationary on the substrate 250.

One or both of the flat plates can be pulled to generate a shear force. For example, when only the bottom flat plate is pulled, a flow (and shear force) is generated in the direction of pulling, because the fluid is dragged in the direction of the pull by viscous drag. In addition, pressure gradient can be applied.

Alternatively, the fluid dispersion can be flowing from an inlet 296 to an outlet 300 to generate the shear force.

In further embodiments, flows (and shear force) can be generated in fluid confined between two rotating cylinders, in a spin coating process, and the like.

In yet other embodiments, flows can be generated by an air knife positioned near a surface of the fluid. The air knife blows air across the surface. The airflow creates a surface tension gradient, which in turn develops a shear force.

Other methods of creating shear flows include, but are not limited to, dip coating in which a substrate is withdrawn from a bath of fluid at an angle, roll coating, slot die coating and the like.

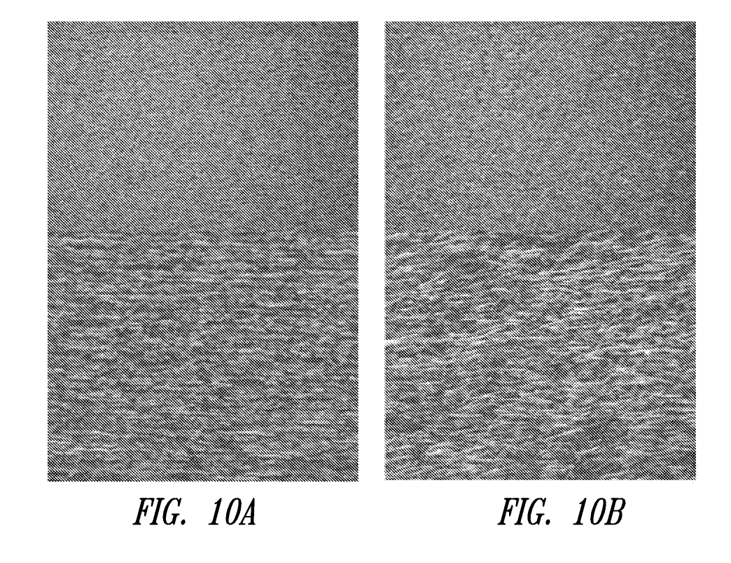

In a further embodiment, fluids that inherently align in a shear flow can be used to enhance the alignment of the nanowires. For example, certain fluids such as liquid crystals can irreversibly align in a flow. Nanowires suspended in this type of fluid thus become anisotropic in a shear flow. FIG. 10A shows the alignment of the liquid crystal itself. FIG. 10B shows a coating of nanowires suspended in the liquid crystal. As can be seen, nanowires are aligned along the same direction as the aligned liquid crystal.

A specific example of such fluid is a lyotropic aqueous based liquid crystal. “Blue” Lyotropic liquid crystal mixture of aqueous solutions of various individual components, including water-soluble blue (B), violet (V), and red (R) dyes. These components are the products of the sulfonation of indanthron, the dibenzimidazole derivative of perylenetetracarboxylic acid, and the dibenzimidazole derivative of naphthalenetetracarboxylic acid, respectively.

It is understood that, regardless of how a shear force is created, its direction and magnitude (e.g., vector) can be regulated by controlling the flow of the fluid, which is known to one skilled in the art.

The degree of the flow-induced alignment is determined by a number of factors, including the magnitude of the shear force, the viscosity of the fluid and the effectiveness of controlling the Brownian motion. Brownian motion refers to the random motion of minute particles suspended in a fluid. Due to Brownian motion, aligned nanowires are susceptible to random reorientation. Because Brownian motion is typically inversely proportional to the viscosity of the fluid, one approach to control or minimize the Brownian motion of the suspended nanowires is to use viscous fluid. Thus, fluids of high viscosity serve two functions—they create larger shear forces for a given velocity of fluid (better alignment), and they can lower or minimize reorientation of the aligned nanowires due to Brownian motion.

### Deposition and Coating

The nanowires can be deposited or coated on a substrate according to methods described in, e.g., U.S. patent application Ser. Nos. 11/504,822 and 11/766,552 and U.S. Provisional Application No. 60/829,292, in the name of Cambrios Technologies Corporation, the assignee of the present application, which references are incorporated herein by reference in their entireties.

One embodiment describes liquid phase coating techniques (e.g., roll coating using a smooth rod). Typically, the alignment of the nanowires can be affected by several factors, including coating methodology and solvent formulation.

One parameter in controlling the coating process is the shear rate (velocity gradient) applied. Typically, the (shear rate)×(time) can determine the degree of alignment. The (shear rate)×(time) refers to the timescale over which the shear rate is applied. Typically, longer (shear rate)×(time) will align a larger fraction of the wires. One example of this result is that larger diameter rods when used on a draw down table produce films that have a higher degree of alignment. In addition, the uniformity of the shear rate applied also affects the degree of alignment. For example, a smooth rod (as opposed to a typical wire covered Mayer rod) can be used to allow for a uniform shear rate to be applied across the coating width.

In addition, solvent properties may also affect the degree of alignment of the nanowire film. Generally, low surface tension organic solvents have provided higher degree of alignment than aqueous based solvents do. For example, organic solvents such as isopropyl alcohol (IPA), n-butanol, and propylene glycol monomethyl ether (PGME) can be used.

The nanowires can be deposited and aligned through multiple-coating passes with a high degree of reproducibility. For certain optical films (e.g., wire grid polarizers), a very dense film of aligned wires is needed. This could be generated by using a concentrated suspension of nanowires as the coating fluid, or by multiple coating passes in which a less concentrated solution of wires are repeatedly applied to the substrate.

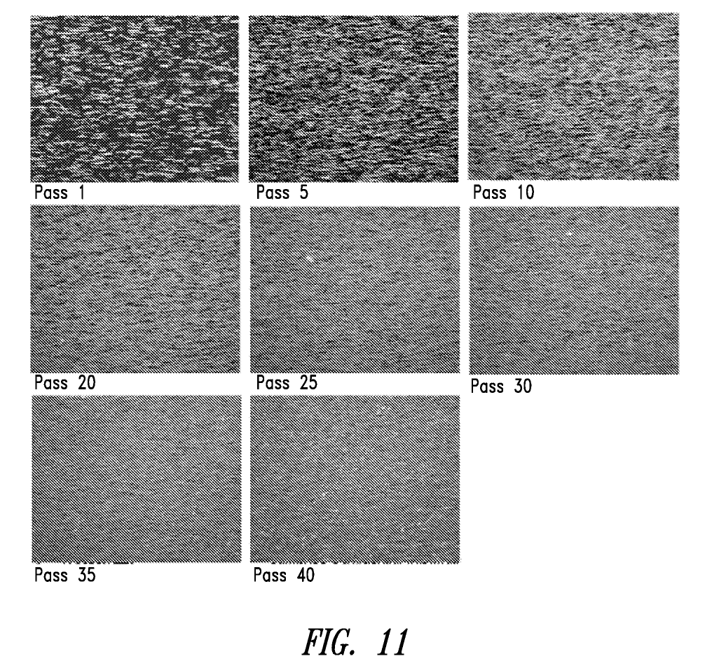

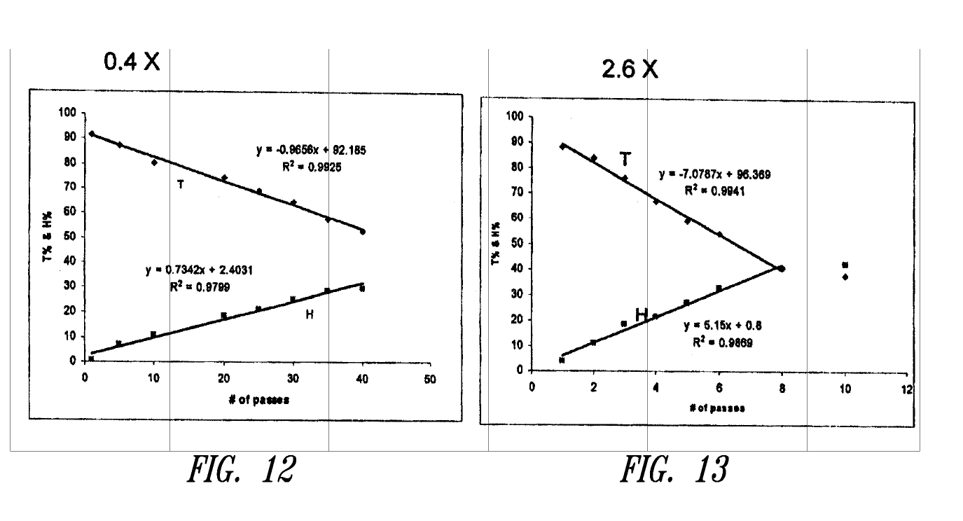

FIG. 11 shows that wire density can be controlled in a reproducible way by using multiple coating passes. Optical data (% transmission and % haze) can be used to demonstrate that a known amount of material is deposited on the substrate that is consistent with each pass. FIGS. 12 and 13 illustrated a linear relationship between the number of coating passes and the % transmission and % haze, which relationship indicates that the same amount of nanowire material is deposited in each pass.

This technique can be used to dial in a specific optical property (e.g., retardation properties of a film by controlling the thickness of the films). As the amount of aligned wires on the surface increases, the retardation (in nm) increases.

### Formation of Nanowire Networks

A further embodiment describes a method of depositing nanowires in non-random and well-defined orientations, thus enhancing the efficiency of forming the conductive network without increasing the optical density of the nanowires. More specifically, nanowires are deposited on a substrate and aligned in a first orientation. Additional depositions and alignment at a second direction result in nanowires crossing one another in a well-defined manner, therefore forming nanowire networks with high efficiency.

Thus, in one embodiment, the method comprises: depositing a first population of nanowires in a first fluid on a substrate; applying a first shear force in a first direction to allow substantially all the first population of nanowires to align their longitudinal orientations with the first direction; immobilizing the first population of nanowires on the substrate; depositing a second population of nanowires in a second fluid on the substrate; applying a second shear force to in a second direction to allow substantially all the second population of nanowires to align their longitudinal orientations with the second direction, wherein the first direction and the second direction are transverse to one another; and immobilizing the second population of nanowires on the substrate, the first population of nanowires and the second population of nanowires forming a network.

In certain embodiments, the step of depositing the first population of nanowires forms a blanket layer of the first fluid on the substrate. The term “blanket layer” refers to a fluid layer formed by the first fluid covering substantially an entire top surface of the substrate. Likewise, in other embodiments, the step of depositing the second population of nanowires also forms a blanket layer of the second fluid on the substrate.

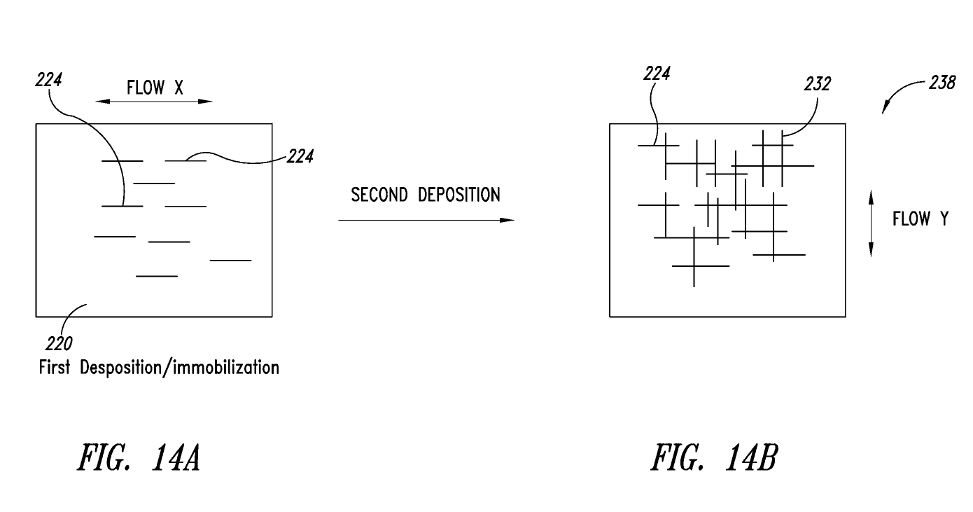

As illustrated in FIG. 14A, a first population of nanowires 224 are deposited on a substrate 220 and induced to orient along a flow in a X direction. The nanowires 224 are then immobilized on the substrate via an affinity for the substrate. Thereafter, a second population of nanowires 232 (shown in FIG. 15B) is deposited on the substrate 220 and subjected to a flow in a Y direction. As shown in FIG. 14B (see, also, FIG. 8B), nanowires 224 and 232 are aligned at right angles and form a network 238.

In certain embodiments, the first direction and the second direction cross at an angle that is at least 30°, or at least 60°, or more typically, at 90°.

An ordered network of nanowires is thus formed, in which nanowires in well-defined orientations cross or overlap with one another. The ordered nature of the network promotes higher probability for the nanowires to interconnect. It can be mathematically proven that these nanowires can conduct charges at higher efficiency than randomly oriented nanowires of the same density and aspect ratio. The number density of nanowires of a given length L that are needed to form a conductive network is “n”. For a non-random, 90 degree network, it can be shown that the number density n=2/L². For a random network, the number of nanowires is higher: n=5.71/L². In other networks, for a given nanowire length, the perpendicular network is 5.71/2=2.86 times more efficient.

The conductivity of the conductive network is inversely proportional to its surface resistivity, sometimes referred to as sheet resistance, which can be measured by known methods in the art. According to various embodiments, the conductive network formed has a surface resistivity of no more than about 10⁶ Ω/square (or Ω/□), more preferably, no more than 10⁴Ω/□, no more than 10²Ω/□, or no more than 50Ω/□.

Unless otherwise specified, the network (or “nanowire network”) is electrically conductive. For example, metal nanowire-based networks are electrically conductive and exhibit high optical clarity. It is noted that in the case wherein the nanowires are seeded biological substances, the network formed can be subjected to a subsequent plating process to become electrically conductive.

In a further embodiment, the first population of nanowires and/or the second population of nanowires can be deposited according to a desired pattern. As will be described in more detail below, the patterning can be effected during the immobilization steps, in which an adhesion layer could be used to pre-coat the substrate according to the desired pattern.

### Formation of a Transparent Conductor

The nanowire networks prepared according to the above methods are suitable for fabricating transparent conductors. In one embodiment, as shown in FIG. 15, a transparent conductor 310 can be prepared by forming a conductive network 314 (as described in connection with FIGS. 15A-15B) on an optically clear substrate 318. The conductive network 114 comprises conductive nanowires 120 (e.g., metal nanowires) in well-defined orientations.

Thus, in one embodiment, a method of fabricating a transparent conductor is described. The method comprises: forming a conductive network on an optically clear substrate, the conductive network including a first population of nanowires and a second population of nanowires, the first population of nanowires being oriented longitudinally along a first direction under a first shear force; the second population of nanowires being oriented longitudinally along a second direction under a second shear force; and depositing a matrix on the conductive network, wherein the first direction and the second direction are transverse to one another.

In a further embodiment, a transparent conductor is described herein, comprising: an optically clear substrate; a first population of nanowires positioned on the substrate, the first population of nanowires orienting longitudinally and parallel along a first direction; and a second population of nanowires positioned on the substrate, the second population of nanowires orienting longitudinally and parallel along a second direction; wherein the first direction and the second direction are transverse to one another.

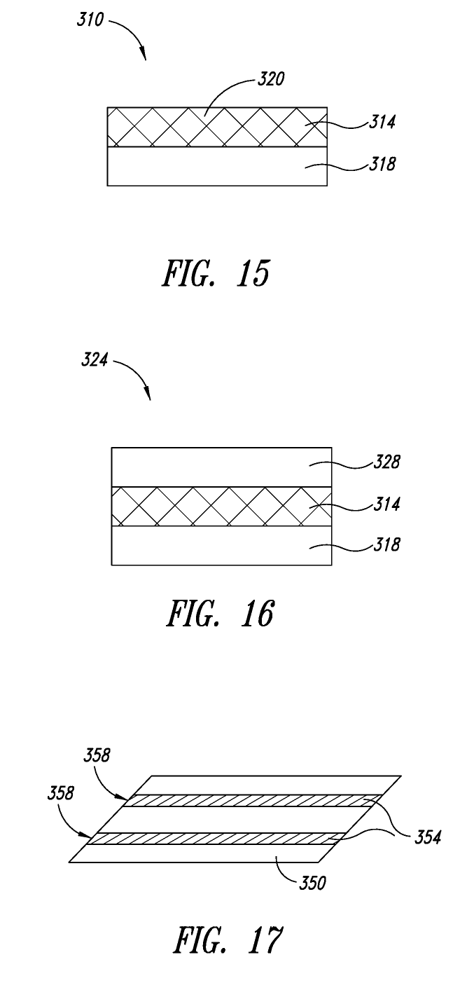

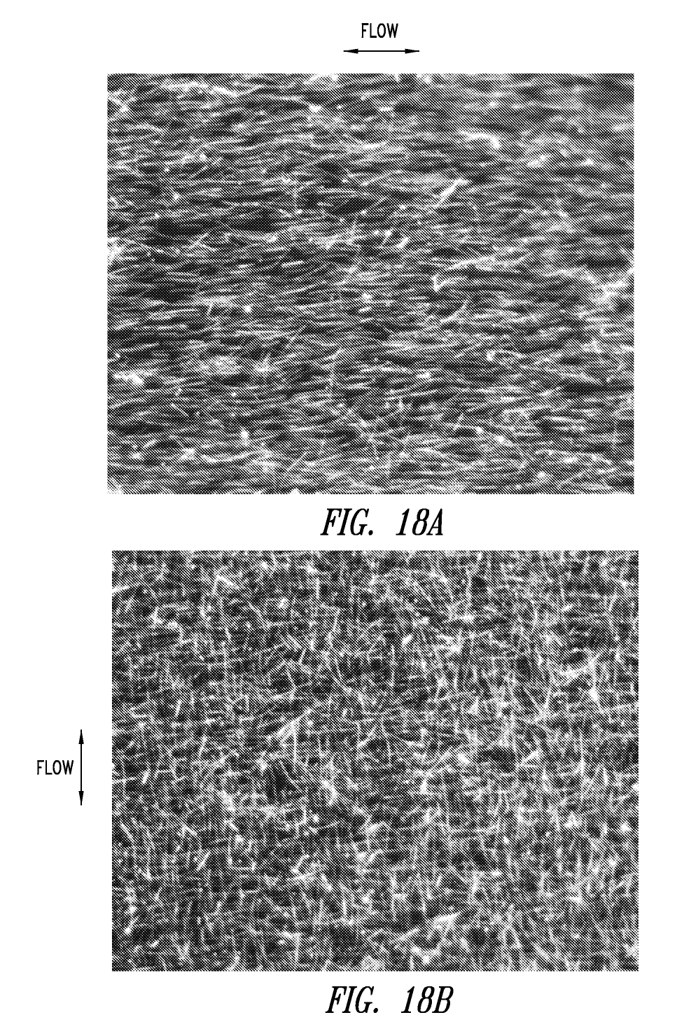

More specifically, a transparent conductor 324 comprises the conductive network 314 dispersed or embedded in a matrix 328 (FIG. 16) “Matrix” refers to an optically clear, solid-state material. The matrix is a host for the nanowires and provides a physical form of the conductive layer. The matrix protects the metal nanowires from adverse environmental factors, such as corrosion and abrasion. In particular, the matrix significantly lowers the permeability of corrosive elements in the environment, such as moisture, trace amount of acids, oxygen, sulfur and the like. A detailed description of fabricating the transparent conductors based on nanowire networks can be found in, e.g., U.S. Provisional Application No. 60/798,878.

Typically, the optical transparence or clarity of the transparent conductor can be quantitatively defined by parameters including light transmission and haze. “Light transmission” refers to the percentage of an incident light transmitted through a medium. In various embodiments, the light transmission of the transparent conductor is at least 50%, at least 60%, at least 70%, or at least 80%. Haze is an index of light diffusion. It refers to the percentage of the quantity of light separated from the incident light and scattered during transmission. Unlike light transmission, which is largely a property of the medium, haze is often a production concern and is typically caused by surface roughness and embedded particles or compositional heterogeneities in the medium. In various embodiments, the haze of the transparent conductor is no more than 10%, no more than 8%, or no more than 5%.

### Immobilization

Following the deposition and alignment of the nanowires, as described above, the nanowires are immobilized on the substrate. Immobilization refers to an adhesive process by which the nanowires are bound to a surface of the substrate, either directly or through an adhesion layer, such that the nanowires remain in their aligned orientations during any subsequent depositions and maneuvers, including fluid flow and air flow.

The nanowires can be bound to the surface of the substrate through any type of affinity, including ionic attraction, chemical bonding, hydrophobic interactions, hydrophilic interactions, and the like. Typically, the surface comprises functional groups, either inherently or by functionalization, which exhibit selective affinities for the nanowires. Examples of suitable functional groups include thiol, amino, carboxylic acid and the like. For glass substrates, these functionalities are well understood and many options are available for solution phase or gas phase silane coatings.

In certain embodiments, the nanowires have sufficient affinity for the substrate that they are immobilized once the fluid is removed. Typically, the substrate has inherent surface functional groups that immobilize the nanowires. For example, glass with an aminosilane such as 3-aminopropyltriethoxysilane H₂N(CH₂)₃Si(OC₂H₅)₃ (Sigma-Aldrich).

In other embodiments, an adhesion layer can be deposited on the surface of the substrate to effect the immobilization. An adhesion layer functionalizes and modified the surface to facilitate the binding of the nanowires to the substrate. The adhesive layer, by definition, exhibits affinities for both the nanowires and the substrate. In certain embodiments, the adhesive layer can be co-deposited with the nanowires. In other embodiments, the adhesive layer can be coated on the substrate prior to depositing the nanowires.

In certain embodiments, multifunctional biomolecules such as polypeptides can be used as the adhesive layer. Polypeptide refers to a polymeric sequence of amino acids (monomers) joined by peptide (amide) bonds. The amino acid monomers in a polypeptide can be the same or different. Amino acids having side chain functionalities (e.g., amino or carboxylic acid groups) are preferred. Examples of suitable polypeptides thus include poly-L-lysine, poly-L-glutamic acid and the like. The polypeptide can be coated on the substrate prior to the nanowire deposition. Alternatively, the polypeptide can be co-deposited on the substrate with the nanowire dispersion. Many substrates, including glass, polyester substrates (e.g., polyethylene terephthalate) exhibit affinities for polypeptides.

In other embodiments, a chemical modification of the substrate can be carried out. For example, functional groups that selectively attract nanowires can be anchored on the substrate prior to the nanowire deposition. For instance, amino or thiol-terminated silanes can self-assemble into a monolayer on the surface of glass, exposing the amino or thiol functional groups for binding with the nanowires.

The adhesion layers described above can be blanket-coated on the entire surface of the substrate, or coated according to a desired pattern. The patterned coating results in an immobilization of the nanowires in the desired pattern. FIG. 17 illustrates a substrate 350 coated with an adhesion layer 354 in selected regions 358. The substrate 350 can be coated with a nanowire dispersion, which can be subjected to any of the flow fields as described herein. The nanowires deposited are therefore immobilized in the regions 358 only. Advantageously, the patterned deposition and immobilization the nanowires make it possible to create conductive circuitries on the surface of the substrate.

### Additional Treatments

One or more additional treatments that facilitate with the deposition, alignment and immobilization steps can be used. For example, a surface treatment of the substrate promotes better wettability for the deposition and/or better adhesion during the immobilization. In particular, plasma surface treatment can be used to modify the molecular structure of the surface of the substrate. Using gases such as argon, oxygen or nitrogen, plasma surface treatment can create highly reactive species at low temperatures. Typically, only a few atomic layers on the surface are involved in the process, so the bulk properties of the polymer remain unaltered by the chemistry. In many instances, plasma surface treatment provides adequate surface activation for enhanced wetting and adhesive bonding. Other exemplary surface treatments include surface washing with a solvent, Corona discharge and UV/ozone treatment, all of which are known to a skilled person in the art.

In certain embodiments, the surface treatment can affect and improve the degree of alignment. More specifically, surface modification can impact the degree of alignment of the nanowire film as it dries.

In other embodiments, post-treatments of the nanowire network can increase the conductivity thereof. Examples of the post-treatments include plasma treatment using inert gases (argon or nitrogen) and other non-oxidizing treatments. Additionally, a pressure treatment can also be applied to enhance the conductivity. The pressure treatment typically involves rolling or otherwise applying pressure evenly across a surface of the network. See, e.g., U.S. patent application Ser. No. 11/504,822.

The alignment of nanowires and formation of nanowire networks are illustrated in more detail by the following non-limiting examples.

### EXAMPLES

### Example 1

### Synthesis of Silver Nanowires

Silver nanowires were synthesized by a reduction of silver nitrate dissolved in ethylene glycol in the presence of poly(vinyl pyrrolidone) (PVP). The method was described in, e.g. Y. Sun, B. Gates, B. Mayers, & Y. Xia, “Crystalline silver nanowires by soft solution processing”, Nanolett, (2002), 2(2) 165-168. Uniform silver nanowires can be selectively isolated by centrifugation or other known methods.

Alternatively, uniform silver nanowires can be synthesized directly by the addition of a suitable ionic additive (e.g., tetrabutylammonium chloride) to the above reaction mixture. The silver nanowires thus produced can be used directly without a separate step of size-selection. This synthesis is described in more detail in U.S. Provisional Application No. 60/815,627, in the name of Cambrios Technologies Corporation, the assignee of the present application, which application is incorporated herein in it entirety.

In the following examples, silver nanowires of 70 nm to 80 nm in width and about 8 μm-25 μm in length were used. Typically, better optical properties (higher transmission and lower haze) can be achieved with higher aspect ratio wires (i.e. longer and thinner).

### Example 2

### Flow-Directed Alignment of Silver Nanowires

An Autoflex EBG5 polyethylene terephthalate (PET) film 5 mm thick was used as a substrate. The surface area was 10×13 cm. The PET substrate was incubated with 0.1 mg/ml poly-L-lysine (MW 500-2000) for an hour. An even layer of poly-L-lysine was coated on the PET substrate. The coating slightly reduced the light transmission of PET (about 92%). The coated PET substrate was then placed on a pivoting shaker.

Thereafter, a dispersion of silver nanowires in a solvent (e.g., low surface tension organic solvent) was deposited on the coated PET substrate. The pivoting shaker rocked for 2 hours, which induced a fluid flow in east-west directions (along the length of the substrate). The rocking motion was carried out at a tilting angle of no more than 18° from the pivoting axis. The substrate was then dried. As shown in FIG. 18A, substantially all of the nanowires are aligned in the east-west directions.

Subsequently, the PET substrate was turned 90° on the pivoting shaker. A second deposition was carried out. The pivoting shaker rocked for 2 hours, which induced a fluid flow in north-south directions (along the width of the substrate). The substrate was then dried. As shown in FIG. 18B, a second population of nanowires are aligned along in the north-south direction. A network of silver nanowires was formed.

Using Fluke 175 True RMS Multimeter, the surface resistivity was measured at about 50-60Ω/□ prior to a plasma treatment. The light transmission was measured at about 80-90%%, and the haze at 4-8%. These optical properties were measured using BYK Gardner Haze-gard Plus.

### Example 3

### Preparation of a Transparent Conductor

The silver nanowire network formed on the PET substrate in Example 2 can be further processed by depositing a matrix material thereon. The matrix material can be prepared by mixing Polyurethane (PU) (Minwax Fast-Drying Polyurethane) in methyl ethyl ketone (MEK) to form a 1:4 (v/v) viscous solution. The matrix material was coated on the silver nanowire network by known methods in the art, for example, curtain coating. The matrix material can be cured for about 3 hours at room temperature, during which the solvent MEK evaporated and the matrix material hardened to form an optically clear matrix. Alternatively, the curing can be done in an oven, e.g., at a temperature of 50° C. for about 2 hours.

A transparent conductor having a conductive network of silver nanowires on the PET substrate (AgNW/PU/PET) can thus be formed. Typically, the presence of the matrix does not alter the electrical conductivity of the silver nanowire network. It can, however, have an anti-glare effect in which the film becomes effectively more transparent.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A polarizer comprising:
a substrate having a surface; and
an array of nanowires arranged parallel to the surface, the nanowires further orienting along a principle axis, wherein, the principle axis is perpendicular to a polarization direction of the polarizer.

2. The polarizer of claim 1, wherein an unpolarized light incident on the polarizer is linearly polarized in the polarization direction and transmits through the polarizer.

3. The polarizer of claim 1, wherein an unpolarized light incident on the polarizer is linearly polarized in a direction orthogonal to the polarization direction and reflects from the polarizer.

4. The polarizer of claim 1 further comprising a matrix layer incorporating the array of nanowires.

5. The polarizer of claim 1 wherein the nanowires are metal nanowires.

6. An optical film comprising:
a matrix layer having a first refractive index, and
an array of nanowires in the matrix layer, the nanowires having a second refractive index, wherein the nanowires are arranged parallel to a surface of the matrix layer and orient along a principle axis.

7. The optical film of claim 6 wherein linearly polarized light incident on the optical film is converted into a circularly polarized light.

8. The optical film of claim 6 wherein circularly polarized light incident on the optical film is converted into a linearly polarized light.

9. The optical film of claim 6 wherein the optical film is a quarter wave retarder.

10. The optical film of claim 6 wherein the nanowires are metal nanowires.

11. A conductive film comprising:
a first population of nanowires aligned in a first direction; and
a second population of nanowires aligned in a second direction, the first direction and the second direction being transverse from one another, wherein the first population of nanowires and the second population of nanowires form a conductive network.

12. The conductive film of claim 11 wherein the conductive network has a surface resistivity of less than 10³Ω/□.

13. The method of claim 11 wherein the conductive network has a light transmission of more than 85% within a wavelength range of between about 300 nm to 800 nm.

14. The conductive film of claim 11 wherein the nanowires are metal nanowires.

15. The conductive film of claim 10 further comprising an optically clear matrix incorporating the conductive network.

16. A method of aligning nanowires comprising:
depositing a first population of nanowires in a first fluid on a substrate, the nanowires in the first population having respective longitudinal orientations;
applying a first shear force in a first direction to allow substantially all the first population of nanowires to align their longitudinal orientations with the first direction;
immobilizing the first population of nanowires on the substrate;
depositing a second population of nanowires in a second fluid on the substrate, the nanowires in the second population having respective longitudinal orientations;
applying a second shear force to in a second direction to allow substantially all the second population of nanowires to align their longitudinal orientations with the second direction, wherein the first direction and the second direction are transverse to one another; and
immobilizing the second population of nanowires on the substrate, the first population of nanowires and the second population of nanowires forming a network.

17. The method of claim 16 wherein the first direction and the second direction cross at a right angle.

18. The method of claim 16 wherein the nanowires are conductive nanowires.

19. The method of claim 16 wherein the network has a surface resistivity of no more than 10³Ω/□.

20. The method of claim 16 wherein the network has a light transmission of more than 85% within a wavelength range of between about 300 nm to 800 nm.

21. The method of claim 16 wherein immobilizing the first population of nanowires comprising removing the first fluid and allowing the first population of nanowires to adhere to the substrate.

22. The method of claim 21 further comprising depositing an adhesive layer, the adhesive layer being positioned between the substrate and the first population of nanowires.

23. The method of claim 22 wherein the adhesive layer comprises a polymer.

24. The method of claim 23 wherein the polymer is a polypeptide.

25. The method of claim 24 wherein the polypeptide is polylysine or polyglutamic acid.

26. The method of claim 22 wherein the adhesive layer is codeposited with the first population of nanowires

27. The method of claim 22 wherein the adhesive layer is deposited on the substrate prior to depositing the first population of nanowires.

28. The method of claim 22 wherein the adhesive layer is a self-assembled monolayer having amino or thiol functional groups.

29. The method of claim 22 wherein pre-treating the substrate comprising applying the adhesive layer according to a desired pattern.

30. The method of claim 29 wherein immobilizing the first population of nanowires comprising allowing the first population of nanowires to adhere to the adhesive layer according to the desired pattern.

31. The method of claim 29 wherein immobilizing the second population of nanowires comprising allowing the second population of nanowires to adhere to the adhesive layer according to the desired pattern.

32. The method of claim 16 wherein the nanowires are surface functionalized.

33. A method of forming a transparent conductor comprising:
forming a conductive network on an optically clear substrate, the conductive network including a first population of nanowires and a second population of nanowires, the first population of nanowires being oriented longitudinally along a first direction under a first shear force; the second population of nanowires being oriented longitudinally along a second direction under a second shear force; and
depositing a matrix on the conductive network, wherein the first direction and the second direction are transverse to one another.

34. The method of claim 33 wherein the first direction and the second direction cross at a right angle.

35. The method of claim 33 wherein the optically clear substrate is flexible.
